(19) United States
(12) Patent Application Publication
(10) Pub. No.: US 2024/0315435 A1
(43) Pub. Date: Sep. 26, 2024

(54) HANDLE, CIRCUIT BOARD ASSEMBLY, AND ELECTRONIC DEVICE

(71) Applicant: Fulian Precision Electronics (Tianjin) Co., LTD., Tianjin (CN)

(72) Inventor: YU-WEN CHANG, New Taipei (TW)

(21) Appl. No.: 18/239,091

(22) Filed: Aug. 28, 2023

(30) Foreign Application Priority Data
Mar. 23, 2023 (CN) 202320592594.4

(51) Int. Cl. A45F 5/10; H05K 1/02

(52) U.S. Cl. CPC A45F 5/10; H05K 1/0203; A45F 2200/0525; H05K 2201/066

(57) ABSTRACT

A handle includes a handle member, two fixing mechanisms, and two fixing mechanisms. The handle member includes a gripping portion and two extending portions connected to two ends of the gripping portion. The gripping portion extends along a first direction, each extending portion extends from the gripping portion along a second direction. The two fixing mechanisms are spaced apart from each other and can connect to a product. Each linkage mechanism is connected between one extending portion and one fixing mechanism. Each linkage mechanism includes a first connecting member and a second connecting member connected to each other. Each first connecting member is rotatably connected to each fixing mechanism. Each second connecting member is telescopically connected to each extending portion along the second direction. The present application further provides a circuit board assembly and an electronic device.

### FIELD

The subject matter herein generally relates to mechanical devices, and more particularly, to a handle, a circuit board assembly, and an electronic device.

### BACKGROUND

As the structures of computer systems become more complex, a density of electronic components on circuit boards, as well as a size and a weight of heat sinks on the circuit boards are increased. In order to facilitate the operation of the circuit board, a handle is provided on the circuit board. However, the handle may affect the layout of the components on the circuit board, and the space utilization rate is low. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view illustrating a handle member in a first position of a handle, according to an embodiment of the present disclosure.

FIG. 2 is similar to FIG. 1 but illustrating the handle member in a second position.

FIG. 3 is an exploded view illustrating the handle in FIG. 1.

FIG. 4 is a diagrammatic view illustrating a linkage mechanism of the handle in FIG. 1.

FIG. 5 is a diagrammatic view illustrating a first connecting member and a fixing mechanism of the handle in FIG. 1.

FIG. 6 is a diagrammatic view illustrating a first connecting member and a second connecting member of the handle in FIG. 1.

FIG. 7 is a diagrammatic view illustrating a circuit board assembly according to an embodiment of the present disclosure.

FIG. 8 is a diagrammatic view illustrating an electronic device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

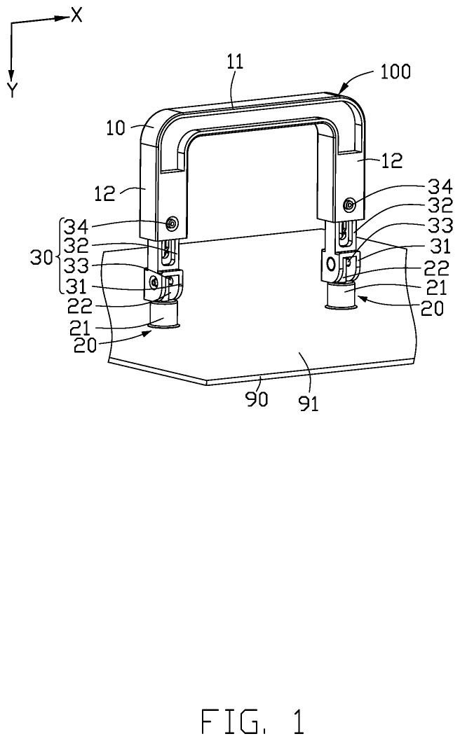

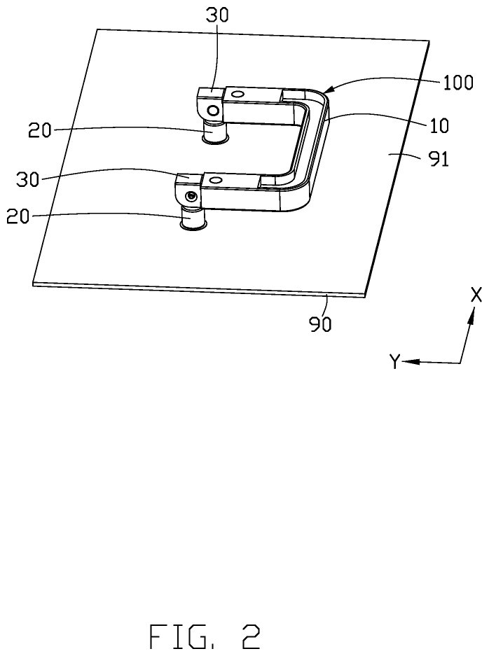

Referring to FIGS. 1 and 2, a handle 100 is provided according to an embodiment of the present disclosure. The handle 100 can be fixed to a product 90, so that an operator can pick up the product 90 by holding the handle 100. The product 90 can be a circuit board, an electronic device, or the like.

The handle 100 includes a handle member 10, two fixing mechanisms 20, and two linkage mechanisms 30. The handle member 10 includes a gripping portion 11 and extending portions 12 connected to two ends of the gripping portion 11. The gripping portion 11 extends along a first direction X, and each extending portion 12 extends from a respective one of the two ends of the gripping portion 11 along a second direction Y. The first direction X and the second direction Y are intersected with each other. In some embodiments, the first direction X is perpendicular to the second direction Y.

The two fixing mechanisms 20 are spaced apart from each other and can be fixed to the product 90. Each linkage mechanism 30 is connected between one of the extending portions 12 and one of the fixing mechanisms 20. Each linkage mechanism 30 includes a first connecting member 31 and a second connecting member 32 connected to each other. The first connecting member 31 is rotatably connected to a corresponding fixing mechanism 20, and the second connecting member 32 is telescopically connected to a corresponding extending portion 12 along the second direction Y.

The handle member 10 can rotate and be telescopic relative to the fixing mechanisms 20 through the linkage mechanisms 30. In operation, when the product 90 needs to be picked up, the handle member 10 is rotated relative to the fixing mechanisms 20 through the first connecting member 31 to a first position, and the gripping portion 11 protrudes from and away from the product 90 (referring to FIG. 1). In the first position, the extending portions 12 is elongated relative to the fixing mechanisms 20 through the second connecting member 32 to increase a distance between the gripping portion 11 and the product 90 for facilitating the operation of the gripping portion 11. When the product 90 does not need to be picked up, the handle member 10 is rotated relative to the fixing mechanisms 20 through the first connecting member 31 to a second position, and the gripping portion 11 is adjacent to the product 90 (referring to FIG. 2). In the second position, the extending portions 12 is shortened relative to the fixing mechanisms 20 through the second connecting member 32 to reduce a space occupied by the handle member 10 and improve space utilization.

In some embodiments, the handle 100 is connected to a first horizontal plane 91 of the product 90. When the handle member 10 is in the first position, the second direction Y is perpendicular to the first horizontal plane 91. When the handle member 10 is in the second position, the second direction Y is parallel to the first horizontal plane 91.

In some embodiments, a chamfered surface is provided at a junction of the gripping portion 11 and the extending portion 12, so as to facilitate the operation of the handle member 10.

In some embodiments, the gripping portion 11 is provided with a coarse layer (not shown). The coarse layer can increase a friction force between the gripping portion 11 and the hand of the operator, so as to facilitate the operation of the handle member 10.

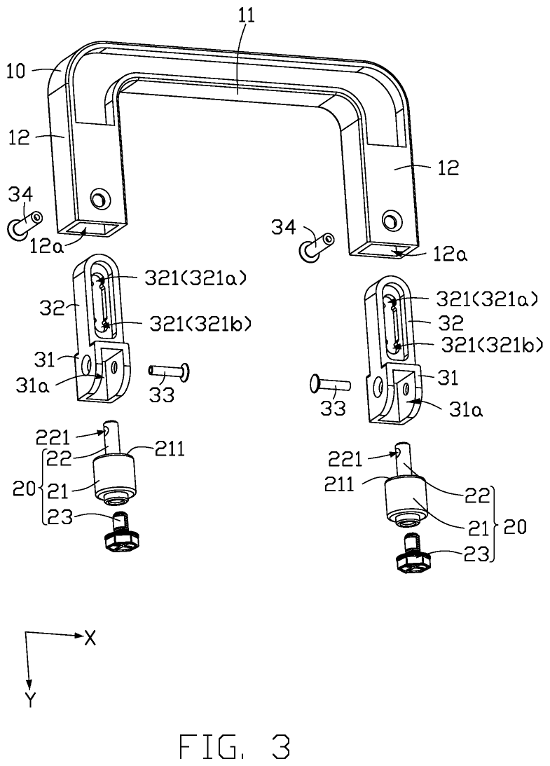

Referring to FIGS. 1 and 3, in some embodiments, each fixing mechanism 20 includes a fixing member 21 and a connecting shaft 22. One side of the fixing member 21 is fixed to the product 90, and another side of the fixing member 21 is fixed to the connecting shaft 22. The first connecting member 31 is rotatably connected to the connecting shaft 22. The fixing member 21 can support the connecting shaft 22, so that the connecting shaft 22 and the product 90 are spaced apart from each other, and the first connecting member 31 and the product 90 are spaced apart from each other. Thus, a risk of damage to the product 90, which is caused by a direct contact between the first connecting member 31 and the product 90 when the first connecting member 31 rotates, can be reduced.

In some embodiments, the fixing member 21 is made of an insulating material. When the product 90 is an electronic product such as a circuit board, the connecting shaft 22 and the product 90 are electrically insulated from each other through the fixing member 21 to improve safety.

In some embodiments, along an axial direction of the connecting shaft 22, an orthogonal projection of the connecting shaft 22 is within a connection surface of the fixing member 21 and the product 90. On one hand, a space required for the rotation between the fixing mechanisms 20 and the first connecting member 31 is reduced, and the space utilization rate is improved. On the other hand, a connection area between each fixing mechanism 20 and the product 90 is increased, thereby increasing a connection strength between each fixing mechanism 20 and the product 90.

In some embodiments, the fixing member 21 is fixed to the connection product 90 through a fastener 23, so as to improve the connection strength between each fixing mechanism 20 and the product 90. The fastener 23 can be a screw.

Referring to FIGS. 1 and 3, in some embodiments, a first concave portion 31a is defined on one end of the first connecting member 31 away from the second connecting member 32, and each fixing mechanism 20 partially extends into the first concave portion 31a. Each linkage mechanism 30 further includes a first pin 33. The first pin 33 is fixed in the first concave portion 31a and penetrates the fixing mechanisms 20 along the first direction X, so that the first connecting member 31 rotates around the first pin 33 relative to the fixing mechanisms 20 to improve the stability of rotation. Moreover, both the first pin 33 and the fixing mechanism 20 are partially disposed in the first concave portion 31a to reduce interference from the external environment.

The another side of the fixing member 21 fixed to the connecting shaft 22 is provided with a first area 211 disposed around the connecting shaft 22. A through hole 221 is defined on the connecting shaft 22, and the through hole 221 penetrates the connecting shaft 22 in a radial direction of the connecting shaft 22. The connecting shaft 22 extends into the first concave portion 31a, and the first pin 33 passes through the through hole 221, so that the first connecting member 31 rotates around the first pin 33 relative to the connecting shaft 22. The first connecting member 31 partially abuts against the first area 211, and the first area 211 can support the first connecting member 31 to improve a connection stability between the fixing mechanism 20 and the first connecting member 31. Moreover, the first area 211 can limit the first connecting member 31 to control a rotation angle of the first connecting member 31, so as to facilitate the handle member 10 to keep at the first position or the second position.

In some embodiments, both ends of the first pin 33 extend through the first concave portion 31a and are exposed from the outer surface of the first connecting member 31, so as to facilitate the adjustment of the first pin 33.

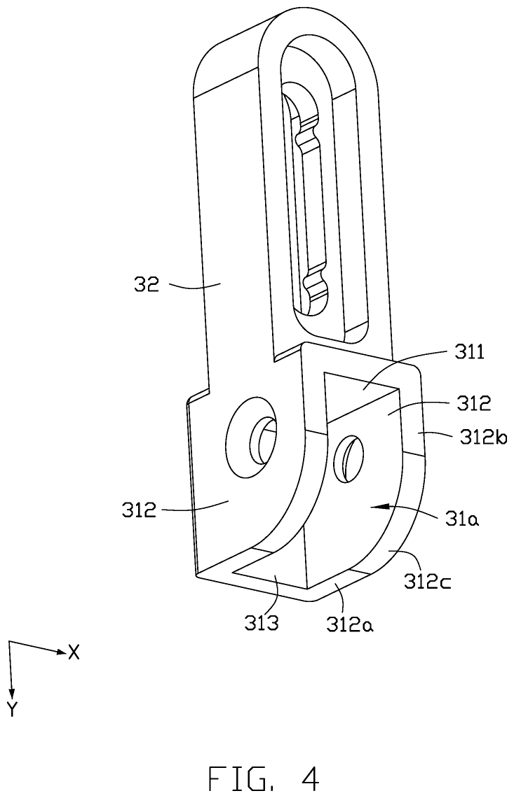

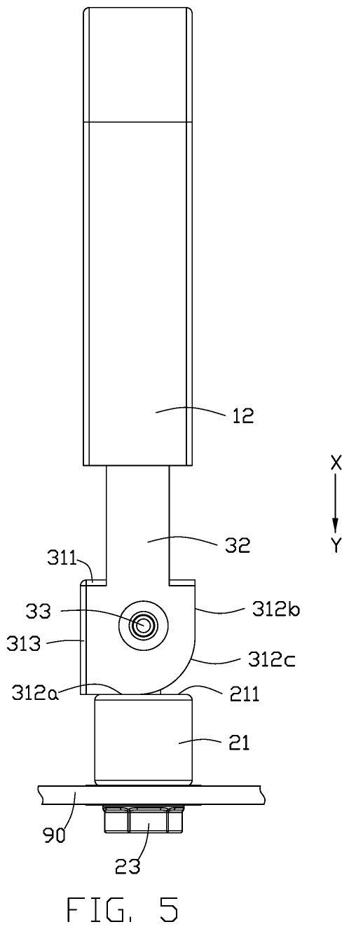

Referring to FIGS. 4 and 5, in some embodiments, the first connecting member 31 includes a bottom wall 311 and two first sidewalls 312. The second connecting member 32 is connected to a side of the bottom wall 311, and the two first sidewalls 312 are connected to another side of the bottom wall 311 away from the second connecting member 32. The first concave portion 31a is defined among the two first sidewalls 312 and the bottom wall 311. Both ends of the first pin 33 are fixed to the two first sidewalls 312.

Each first sidewall 312 includes a first plane 312a, a second plane 312b, and an arc surface 312c connected between the first plane 312a and the second plane 312b. When viewed along the first direction X, the first plane 312a is opposite to the bottom wall 311, an extending direction of the second plane 312b intersects an extending direction of the first plane 312a, and an end of the second plane 312b away from the arc surface 312c is connected to the bottom wall 311. Any one of the first plane 312a, the second plane 312b, and the arc surface 312c can abut against the first area 211.

In some embodiments, when viewed along the first direction X, the extending direction of the first plane 312a is perpendicular to the second direction Y, the extending direction of the second plane 312b is parallel to the second direction Y, and the extending direction of the second plane 312b is perpendicular to the extending direction of the first plane 312a.

When the first plane 312a abuts against the first area 211, the first area 211 limits the handle member 10 at the first position without any external force. When the first plane 312a abuts against the first area 211, the first area 211 limits the handle member 10 at the second position without any external force. When the first connecting member 31 rotates under an external force, the arc surface 312c abuts against the first area 211 to improve the stability of the rotation of the handle member 10.

When viewed along the first direction X, along the radial direction of the first pin 33, a distance between an axis of the first pin 33 and the first plane 312a, a distance between the axis of the first pin 33 and the second plane 312b, and a distance between the axis of the first pin 33 and the arc surface 312c are equal.

Referring to FIGS. 4 and 5, in some embodiments, the first connecting member 31 further includes a second sidewall 313 connected between the two first sidewalls 312. When viewed along the first direction X, the second sidewall 313 extends from the bottom wall 311 along the second direction Y to an end of the first plane 312a away from the arc surface 312c. A corner between the second sidewall 313 and the first plane 312a can limit the rotation of the first connecting member 31 toward the first plane 312a away from the arc surface 312c, thereby limiting the rotation angle of the handle member 10 and reducing the risk of interference between the handle member 10 and other structures on the product 90.

Referring to FIGS. 1 and 3, in some embodiments, an end of the extending portion 12 away from the gripping portion 11 is provided with a second concave portion 12a extending along the second direction Y. Each linkage mechanism 30 further includes a second pin 34 fixed in the second concave portion 12a. One end of the second connecting member 32 extends into the second concave portion 12a. A plurality of limiting holes 321 are defined on the second connecting member 32 and are spaced apart from each other in the second direction Y. The second pin 34 can be selectively inserted into one of the limiting holes 321 to adjust a telescopic length of the extending portion 12 relative to the second connecting member 32, thereby adjusting the distance between the gripping portion 11 and each fixing mechanism 20. Moreover, both the second pin 34 and the second connecting member 32 are partially disposed in the second concave portion 12a, so as to reduce interference from the external environment.

In some embodiments, both ends of the second pin 34 extend through the second concave portion 12a and are exposed from the outer surface of the extending portion 12, so as to facilitate the adjustment of the second pin 34.

In some embodiments, two limiting holes 321 are defined on the second connecting member 32. One of the two limiting holes 321 is defined as a first limiting hole 321a away from the first connecting member 31, and another one of the two limiting holes 321 close to the first connecting member 31 is defined as a second limiting hole 321b. A position of the second limiting hole 321b can correspond to a position of the second pin 34 when the second connecting member 32 completely extends into the second concave portion 12a. At the time, the end of the extending portion 12 provided with the second concave portion 12a also abuts against the bottom wall 311, so as to improve the utilization rate of the space between the second connecting member 32 and the extending portion 12.

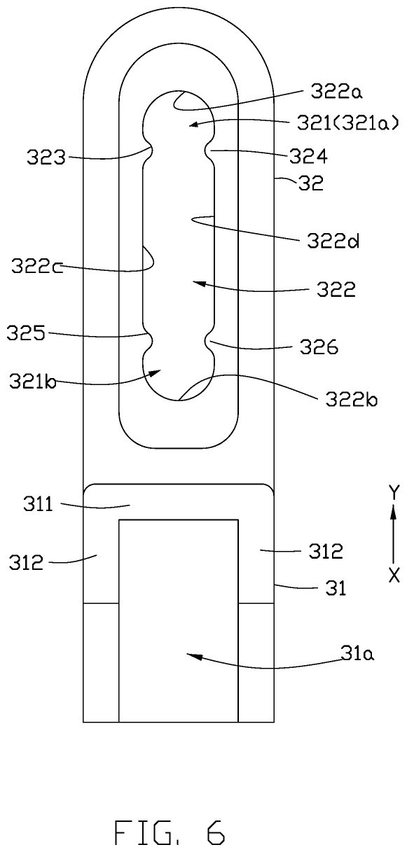

Referring to FIG. 6, in some embodiments, the second connecting member 32 defines a through slot 322 extending along the second direction Y, and the second pin 34 is slidably disposed in the through slot 322 along the second direction Y.

The through slot 322 includes a first inner wall 322a, a second inner wall 322b, a third inner wall 322c, and a fourth inner wall 322d. The first inner wall 322a and the second inner wall 322b are away from each other along the second direction Y. The third inner wall 322c and the fourth inner wall 322d are disposed between the first inner wall 322a and the second inner wall 322b and away from each other. A first protrusion 323 protrudes from the third inner wall 322c and adjacent to the first inner wall 322a. A second protrusion 324 protrudes from the fourth inner wall 322d and adjacent to the first inner wall 322a. The first protrusion 323 and the second protrusion 324 face each other. The first protrusion 323, the second protrusion 324, and the first inner wall 322a cooperatively define the first limiting hole 321a. A third protrusion 325 protrudes from the third inner wall 322c and adjacent to the second inner wall 322b. A fourth protrusion 326 protrudes from the fourth inner wall 322d and adjacent to the second inner wall 322b. The third protrusion 325 and the fourth protrusion 326 are face each other. The third protrusion 325, the fourth protrusion 326 and the second inner wall 322b cooperatively define the second limiting hole 321b.

During using the handle 100, when the second pin 34 slides to the first protrusion 323 and the second protrusion 324 in the through slot 322, the first protrusion 323 and the second protrusion 324 stop the second pin 34 so that the operator can perceive the first limiting hole 321a, thereby facilitating the operator to insert the second pin 34 into the first limiting hole 321a. When the second pin 34 slides to the third protrusion 325 and the fourth protrusion 326 in the through slot 322, the third protrusion 325 and the fourth protrusion 326 stop the second pin 34 so that the operator can perceive the second limiting hole 321b, thereby facilitating the operator to insert the second pin 34 into the second limiting hole 321b.

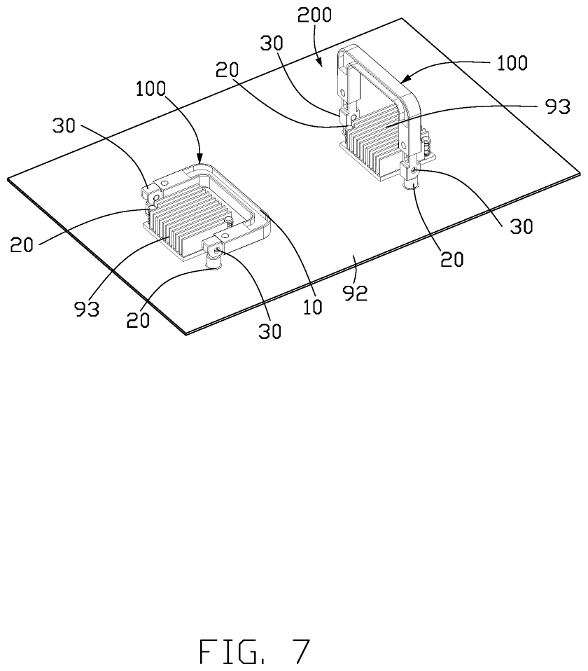

Referring to FIG. 7, a circuit board assembly 200 is further provided according to an embodiment of the present disclosure. The circuit board assembly 200 includes a substrate 92 and a component 93 connected to the substrate 92. The circuit board assembly 200 further includes the handle 100 described in any one of the above embodiments, and at least a portion of the component 93 is disposed between the two fixing mechanisms 20.

In some embodiments, the component 93 is a heat sink. The extending portions 12 are elongated relative to the fixing mechanisms 20 through the second connecting member 32. Thus, the risk of interference between the component 93 and the gripping portion 11 in a height direction of the component 93 can be reduced.

In some embodiments, the fastener 23 passes through the substrate 92. One end of the fastener 23 is fixed to the fixing member 21, and another end of the fastener 23 abuts against the substrate 92 away from the fixing member 21 to improve the connection strength.

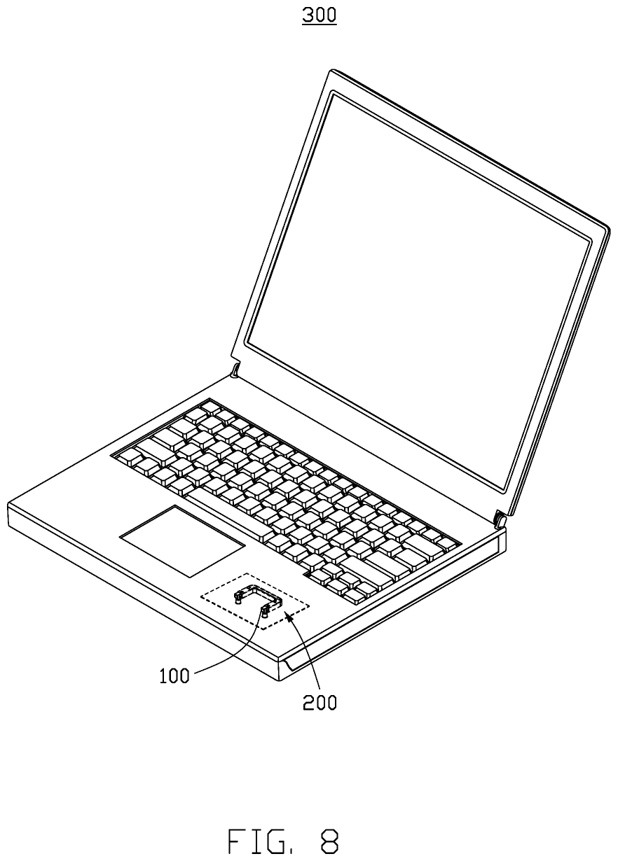

Referring to FIG. 8, an electronic device 300 is further provided according to an embodiment of the present disclosure. The electronic device 300 includes the handle 100 in any of the above embodiments or the circuit board assembly 200 in any of the above embodiments.

In the present application, the handle member 10 can be rotated and stretched relative to the fixing mechanisms 20 through the linkage mechanisms 30. The handle member 10 can rotate and be telescopic relative to the fixing mechanisms 20 through the linkage mechanisms 30. In operation, when the product 90 needs to be picked up, the handle member 10 is rotated relative to the fixing mechanisms 20 through the first connecting member 31 to a first position, and the gripping portion 11 protrudes from and away from the product 90. In the first position, the extending portions 12 is elongated relative to the fixing mechanisms 20 through the second connecting member 32 to increase a distance between the gripping portion 11 and the product 90 for facilitating the operation of the gripping portion 11. When the product 90 does not need to be picked up, the handle member 10 is rotated relative to the fixing mechanisms 20 through the first connecting member 31 to a second position, and the gripping portion 11 is adjacent to the product 90. In the second position, the extending portions 12 is shortened relative to the fixing mechanisms 20 through the second connecting member 32 to reduce a space occupied by the handle member 10 and improve space utilization.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A handle configured to be fixed to a product, comprising:
a handle member comprising a gripping portion and two extending portions connected to two ends of the gripping portion, the gripping portion extending along a first direction, each of the two extending portions extending from a respective one of the two ends of the gripping portion along a second direction, the first direction and the second direction being different from each other;
two fixing mechanisms spaced apart from each other and configured to connect to the product; and
two linkage mechanisms, each of the two linkage mechanisms connected between one of the two extending portions and one of the two fixing mechanisms; each of the two linkage mechanisms comprising a first connecting member and a second connecting member connected to each other, the first connecting member rotatably connected to a corresponding of the two fixing mechanisms, and the second connecting member telescopically connected to a corresponding of the two extending portions along the second direction.

2. The handle of claim 1, wherein a first concave portion is defined on one end of the first connecting member away from the second connecting member, each of the two fixing mechanisms partially extends into the first concave portion, each of the two linkage mechanisms further comprises a first pin, the first pin is fixed in the first concave portion and penetrates each of the two fixing mechanisms along the first direction.

3. The handle of claim 2, wherein each of the two fixing mechanisms comprises a fixing member and a connecting shaft, one side of the fixing member is configured to fix to the product, another side of the fixing member is fixed to the connecting shaft, the another side of the fixing member fixed to the connecting shaft is provided with a first area, the first area is disposed around the connecting shaft, a through hole is defined on the connecting shaft, the connecting shaft extends into the first concave portion, the first pin passes through the through hole, and the first connecting member partially abuts against the first area.

4. The handle of claim 3, wherein the first connecting member comprises a bottom wall and two first sidewalls, the second connecting member is connected to a side of the bottom wall, the two first sidewalls are connected to another side of the bottom wall away from the second connecting member, the first concave portion is further defined among the two first sidewalls and the bottom wall, each of the two first sidewalls comprises a first plane, a second plane, and an arc surface connected between the first plane and the second plane, when viewed along the first direction, the first plane is opposite to the bottom wall, an extending direction of the second plane intersects an extending direction of the first plane, an end of the second plane away from the arc surface is connected to the bottom wall, and any one of the first plane, the second plane, and the arc surface is configured to abut against the first area.

5. The handle of claim 4, wherein the first connecting member further comprises a second sidewall connected between the two first sidewalls, when viewed along the first direction, the second sidewall extends from the bottom wall along the second direction to an end of the first plane away from the arc surface.

6. The handle of claim 1, wherein an end of one of the two extending portions away from the gripping portion is provided with a second concave portion, each of the two linkage mechanisms further comprises a second pin fixed in the second concave portion, one end of the second connecting member extends into the second concave portion, a plurality of limiting holes are defined on the second connecting member and are spaced apart from each other in the second direction, the second pin is configured to be selectively inserted into one of the plurality of limiting holes.

7. The handle of claim 6, wherein the plurality of limiting holes comprises two limiting holes, one of the two limiting holes is defined as a first limiting hole away from the first connecting member, and another one of the two limiting holes close to the first connecting member is defined as a second limiting hole.

8. The handle of claim 7, wherein the second connecting member defines a through slot extending along the second direction, and the second pin is slidably disposed in the through slot along the second direction, the through slot comprises a first inner wall, a second inner wall, a third inner wall, and a fourth inner wall, the first inner wall and the second inner wall are away from each other along the second direction, the third inner wall and the fourth inner wall are disposed between the first inner wall and the second inner wall and away from each other, a first protrusion protrudes from the third inner wall and adjacent to the first inner wall, a second protrusion protrudes from the fourth inner wall and adjacent to the first inner wall, the first protrusion and the second protrusion face each other, the first protrusion, the second protrusion, and the first inner wall cooperatively define the first limiting hole with the first inner wall, a third protrusion protrudes from the third inner wall and adjacent to the second inner wall, a fourth protrusion protrudes from the fourth inner wall and adjacent to the second inner wall, the third protrusion and the fourth protrusion face each other, the third protrusion, the fourth protrusion, and the fourth inner wall define the second limiting hole.

9. A circuit board assembly, comprising:
a substrate;
a component disposed on the substrate; and
a handle configured to be fixed to the substrate comprising:
a handle member comprising a gripping portion and two extending portions connected to two ends of the gripping portion, the gripping portion extending along a first direction, each of the two extending portions extending from a respective one of the two ends of the gripping portion along a second direction, the first direction and the second direction being different from each other;
two fixing mechanisms spaced apart from each other and configured to connect to the substrate; and
two linkage mechanisms, each of the two linkage mechanisms connected between one of the two extending portions and one of the two fixing mechanisms; each of the two linkage mechanisms comprising a first connecting member and a second connecting member connected to each other, the first connecting member rotatably connected to a corresponding of the two fixing mechanisms, and the second connecting member telescopically connected to a corresponding of the two extending portions along the second direction;
wherein at least a portion of the component is disposed between the two fixing mechanisms.

10. The circuit board assembly of claim 9, wherein a first concave portion is defined on one end of the first connecting member away from the second connecting member, each of the two fixing mechanisms partially extends into the first concave portion, each of the two linkage mechanisms further comprises a first pin, the first pin is fixed in the first concave portion and penetrates each of the two fixing mechanisms along the first direction.

11. The circuit board assembly of claim 10, wherein each of the two fixing mechanisms comprises a fixing member and a connecting shaft, one side of the fixing member is configured to fix to the substrate, another side of the fixing member is fixed to the connecting shaft, the another side of the fixing member fixed to the connecting shaft is provided with a first area, the first area is disposed around the connecting shaft, a through hole is defined on the connecting shaft, the connecting shaft extends into the first concave portion, the first pin passes through the through hole, and the first connecting member partially abuts against the first area.

12. The circuit board assembly of claim 11, wherein the first connecting member comprises a bottom wall and two first sidewalls, the second connecting member is connected to a side of the bottom wall, the two first sidewalls are connected to another side of the bottom wall away from the second connecting member, the first concave portion is further defined among the two first sidewalls and the bottom wall; each of the two first sidewalls comprises a first plane, a second plane, and an arc surface connected between the first plane and the second plane, when viewed along the first direction, the first plane is opposite to the bottom wall, an extending direction of the second plane intersects an extending direction of the first plane, an end of the second plane away from the arc surface is connected to the bottom wall, and any one of the first plane, the second plane, and the arc surface is configured to abut against the first area.

13. The circuit board assembly of claim 12, wherein the first connecting member further comprises a second sidewall connected between the two first sidewalls, when viewed along the first direction, the second sidewall extends from the bottom wall along the second direction to an end of the first plane away from the arc surface.

14. The circuit board assembly of claim 9, wherein an end of one of the extending portions away from the gripping portion is provided with a second concave portion, each of the two linkage mechanisms further comprises a second pin fixed in the second concave portion, one end of the second connecting member extends into the second concave portion, a plurality of limiting holes are defined on the second connecting member and are spaced apart from each other in the second direction, the second pin is configured to be selectively inserted into one of the plurality of limiting holes.

15. The circuit board assembly of claim 14, wherein the plurality of limiting holes comprises two limiting holes, one of the two limiting holes is defined as a first limiting hole away from the first connecting member, and another one of the two limiting holes close to the first connecting member is defined as a second limiting hole.

16. The circuit board assembly of claim 15, wherein the second connecting member defines a through slot extending along the second direction, and the second pin is slidably disposed in the through slot along the second direction; the through slot comprises a first inner wall, a second inner wall, a third inner wall, and a fourth inner wall, the first inner wall and the second inner wall are away from each other along the second direction, the third inner wall and the fourth inner wall are disposed between the first inner wall and the second inner wall and away from each other, a first protrusion protrudes from the third inner wall and adjacent to the first inner wall, a second protrusion protrudes from the fourth inner wall and adjacent to the first inner wall, the first protrusion and the second protrusion face each other, the first protrusion, the second protrusion and the first inner wall cooperatively define the first limiting hole with the first inner wall; a third protrusion protrudes from the third inner wall and adjacent to the second inner wall, a fourth protrusion protrudes from the fourth inner wall and adjacent to the second inner wall, the third protrusion and the fourth protrusion face each other, the third protrusion, the fourth protrusion and the fourth inner wall define the second limiting hole.

17. An electronic device, comprising:
a handle configured to be fixed to a product, comprising:
a handle member comprising a gripping portion and two extending portions connected to two ends of the gripping portion, the gripping portion extending along a first direction, each of the two extending portions extending from a respective one of the two ends of the gripping portion along a second direction, the first direction and the second direction being different from each other;
two fixing mechanisms spaced apart from each other and configured to connect to the product; and
two linkage mechanisms, each of the two linkage mechanisms connected between one of the two extending portions and one of the two fixing mechanisms; each of the two linkage mechanisms comprising a first connecting member and a second connecting member connected to each other, the first connecting member rotatably connected to a corresponding of the two fixing mechanisms, and the second connecting member telescopically connected to a corresponding of the two extending portions along the second direction.

18. The electronic device of claim 17, wherein a first concave portion is defined on one end of the first connecting member away from the second connecting member, each of the two fixing mechanisms partially extends into the first concave portion, each of the two linkage mechanisms further comprises a first pin, the first pin is fixed in the first concave portion and penetrates each of the two fixing mechanisms along the first direction.

19. The electronic device of claim 18, wherein each of the two fixing mechanisms comprises a fixing member and a connecting shaft, one side of the fixing member is configured to fix to the product, another side of the fixing member is fixed to the connecting shaft, the another side of the fixing member fixed to the connecting shaft is provided with a first area, the first area is disposed around the connecting shaft, a through hole is defined on the connecting shaft, the connecting shaft extends into the first concave portion, the first pin passes through the through hole, and the first connecting member partially abuts against the first area.

20. The electronic device of claim 17, further comprising a substrate and a component disposed on the substrate; wherein at least a portion of the component is disposed between the two fixing mechanisms.
